(19) United States
(12) Patent Application Publication
(10) Pub. No.: US 2007/0162816 A1
(43) Pub. Date: Jul. 12, 2007

(54) Method for constructing a parity check matrix of an irregular low density parity check code

(75) Inventors: Dong-Ho Kim, Seoul (KR); Ye-Hoon Lee, Suwon-si (KR); Nam-Shik Kim, Yongin-si (KR); Hyun-Cheol Park, Daejeon (KR); Cheol-Woo You, Seoul (KR)

Correspondence Address: DILWORTH & BARRESE, LLP, 333 EARLE OVINGTON BLVD., SUITE 702, UNIONDALE, NY, 11553, US

(73) Assignees: SAMSUNG ELECTRONICS CO., LTD., Suwon-si (KR); Korea Advanced Institute of Science and Technology (KAIST), Yusong-gu (KR)

(21) Appl. No.: 11/582,007

(22) Filed: Oct. 17, 2006

(30) Foreign Application Priority Data
Oct. 17, 2005 (KR) 97687/2005

(51) Int. Cl. H03M 13/00

(52) U.S. Cl. 714/752

(57) ABSTRACT

A method for generating a parity check matrix of a Low Density Parity Check (LDPC) code. A base matrix is generated in which elements with a value of 1 are arranged at predefined distances. The elements with the value of 1 in the base matrix are replaced with predefined sub-matrices. The method can improve the performance of the LDPC code by implementing the parity check matrix in which the number of 4-cycles or 6-cycles adversely affecting the LDPC code performance is minimized.

### PRIORITY

This application claims priority under 35 U.S.C. § 119 to an application entitled “Method for Constructing a Parity Check Matrix of a Low Density Parity Check Code” filed in the Korean Intellectual Property Office on Oct. 17, 2005 and assigned Ser. No. 2005-97687, the contents of which are incorporated herein by reference.

### BACKGROUND OF THE INVENTION

1. Field of the Invention

The present invention generally relates to channel coding technology in a communication system, and more particularly to a method for constructing a parity check matrix of a Low Density Parity Code (LDPC) code in a communication system.

2. Description of the Related Art

Because Low Density Parity Check (LDPC) codes have a superior performance and lower decoding complexity than turbo codes and can be processed in parallel at a high rate, they are attracting much interest as a coding scheme suitable for the Fourth-Generation (4G) mobile communication systems.

The LDPC codes first proposed by Gallager in 1962 are defined as linear block codes using a parity check matrix H with a large number of 0's. Since code complexity has hindered the implementation of technology to use the LDPC codes, the LDPC codes have been almost forgotten. Mackay and Neal have rediscovered the LDPC codes and have verified that they have a superior performance using a simple probabilistic decoding method of Gallager.

One of obstacle elements in implementing the LDPC code is coding complexity. The complexity of coding performed by matrix multiplication increases in proportion to the square of the length of a code. To reduce this complexity, cyclic codes have been proposed. Decoding complexity can be reduced only if a code has a sparse parity check matrix. Most of the known cyclic codes do not satisfy this condition.

Finite geometry codes have also been proposed. These codes exhibit a significantly improved iterative decoding performance through the use of cyclic characteristics and a possible sparse parity check matrix. The cyclic finite geometry codes are useful only in a limited range of the code length and rate. As a column weight increases in proportion to the code length, the decoding complexity increases.

### SUMMARY OF THE INVENTION

It is, therefore, an object of the present invention to provide a method for constructing a parity check matrix of a Low Density Parity Check (LDPC) code that can reduce the coding complexity.

It is another object of the present invention to provide a method for constructing a parity check matrix of a Low Density Parity Check (LDPC) code that can implement a parity check matrix in which a 4-cycle or 6-cycle does not occur.

It is another object of the present invention to provide a method for constructing a parity check matrix of a Low Density Parity Check (LDPC) code that can minimize the coding complexity by eliminating an inverse matrix operation during the coding process.

It is another object of the present invention to provide a method for constructing a parity check matrix of a Low Density Parity Check (LDPC) code that can construct a quasi-cyclic code having cyclic characteristics to reduce the coding complexity.

In accordance with an aspect of the present invention, there is provided a method for generating a parity check matrix of a Low Density Parity Check (LDPC) code, including generating a base matrix in which elements with -a value of 1 are arranged at predefined distances; and replacing the elements with the value of 1 in the base matrix with predefined sub-matrices, and generating a parity check matrix.

The base matrix is generated by setting a code rate of-the LI)PC code, generating at least two Integer Distance Cyclic Matrices (IDCMs) mapped to the code rate, and arranging the at least two IDCMs. The sub-matrices are irregular sub-matrices.

### BRIEF DESCRIPTION OF THE DRAWINGS

The above and other objects and aspects of the present invention will be more clearly understood from the following detailed description taken in conjunction with the accompanying drawings, in which:

FIG. 1 illustrates an example of an Integer Distance Cyclic Matrix (IDCM) for constructing a base matrix corresponding to a basis of a Low Density Parity Check (LDPC) code in accordance with the present invention;

FIG. 2 illustrates an example of an Integer Distance Quasi-Cyclic Matrix (IDQCM) mapped to the IDCM of FIG. 1;

FIG. 3 illustrates an example of a base matrix for generating a quasi-cyclic (QC)-LDPC code with a code rate of ½ in accordance with the present invention;

FIG. 4 illustrates an example of a parity check matrix generated by replacing IDCMs for constructing the base matrix of FIG. 3. with IDQCMs; and

FIG. 5 is a flowchart illustrating a process for generating a parity check matrix in accordance with the present invention.

### DETAILED DESCRIPTION OF THE PREFERRED EMBODIMENTS

Preferred embodiments of the present invention will be described in detail herein below with reference to the accompanying drawings such that those skilled in the art can readily implement the present invention.

Hereinafter, the present invention proposes a method for constructing a parity check matrix of a Low Density Parity Check (LDPC) code. The present invention constructs a quasi-cyclic code having cyclic characteristics to reduce the coding complexity. Further, the present invention provides a method for constructing an irregular parity check matrix of an LDPC code that can improve the decoding performance by implementing a parity check matrix capable of avoiding a 4-cycle or 6-cycle when a quasi-cyclic code is constructed.

When a code rate is set in the parity check matrix construction method of the present invention, at least two Integer Distance Cyclic Matrices (IDCMs) mapped to the code rate are selected. When the selected IDCMs are combined, a base matrix is generated. When the IDCMs for constructing the base matrix are replaced with Integer Distance Quasi-Cyclic Matrices (IDQCMs) mapped thereto, a parity check matrix is generated in which a 4-cycle or 6-cylce does not occur, that is, the number of 4-cycles or 6-cycles is reduced.

The IDQCM is generated by replacing elements with the value of 1 for constructing the associated IDCM with predefined sub-matrices, i.e., irregular sub-matrices.

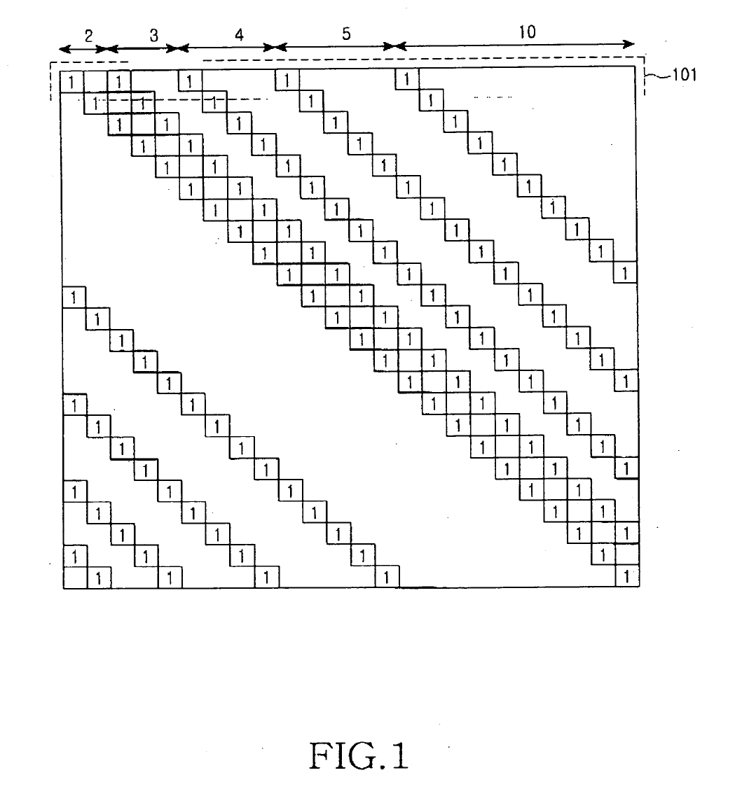

FIG. 1 illustrates an example of an IDCM for constructing a base matrix corresponding to a basis of an LDPC code in accordance with the present invention. As illustrated in FIG. 1, the IDCM is constructed by arranging elements with the value of 1 at predefined distances and shifting a generated row (codeword) 101 by 1.

In FIG. 1, the distance between the 1^{st} and 2^{nd} elements with the value of 1 is 2. The distance between the 2^{nd} and 3^{rd} elements with the value of 1 is 3. The distance between the 3^{rd} and 4^{th} elements with the value of 1 is 4. The distance between the 4^{th} and 5^{th} elements with the value of 1 is 5. The distance between the 5^{th} and 6^{th} elements with the value of 1 is 10. For convenience of explanation, the IDCM with the above-described distance characteristics is expressed by IDCM [2,3,4,5,10].

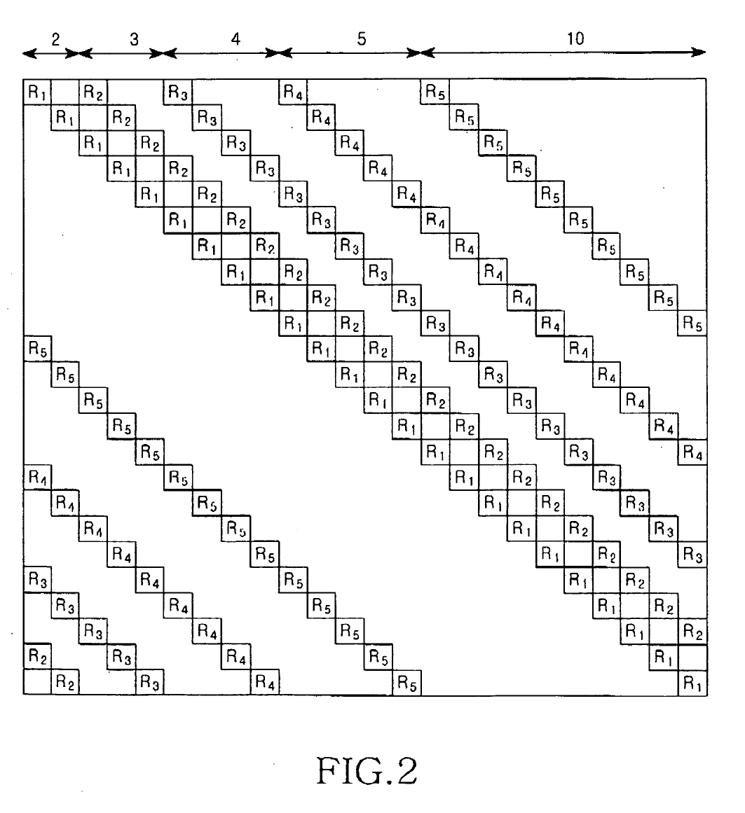

FIG. 2 illustrates an example of an IDQCM mapped to the IDCM of FIG. 1. As illustrated in FIG. 2, the 1^{st} diagonal elements for constructing the IDCM are replaced with sub-matrices R₁. The 2^{nd} diagonal elements for constructing the IDCM are replaced with sub-matrices R₂. The 3^{rd} diagonal elements for constructing the IDCM are replaced with sub-matrices R₃. The 4^{th} diagonal elements for constructing the IDCM are replaced with sub-matrices R₄. The 5^{th} diagonal elements for constructing the IDCM are replaced with sub-matrices R₅. For convenience of explanation, the IDQCM with the above-described distance characteristics is expressed by IDQCM [2,3,4,5,10|R₁,R₂,R₃,R₄,R₅].

The sub-matrices are constructed with small-sized block matrices. The block matrices include at least one of a zero matrix, a unit matrix and a quasi-cyclic matrix generated by shifting the unit matrix to the right by a predefined value. The block matrices are irregularly constructed inside the sub-matrices. Elements with the value of 1 are irregularly distributed in the sub-matrices.

The sub-matrix is denoted by Rᵢ where i is a sub-matrix index. The sub-matrix is predefined according to code rate.

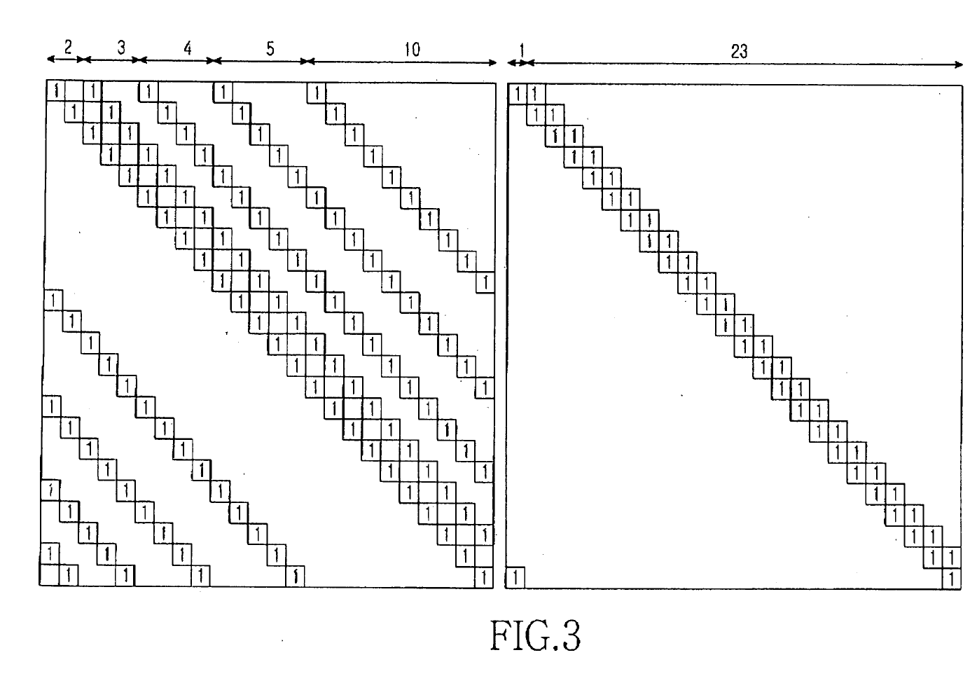

FIG. 3 illustrates an example of a base matrix for generating a Quasi-Cyclic (QC)-LDPC code with a code rate of ½ in accordance with the present invention.

As illustrated in FIG. 3, the base matrix of the QC-LDPC code with the code rate of ½ is generated by combining IDCM [2,3,4,5,10] and IDCM [1,23]. The base matrix B can be expressed as shown in Equation (1).
B=[IDCM[2,3,4,5,10]|IDCM[1,23]] (1)

In the generated base matrix, two 4-cycles, fifty-eight 6-cycles, and forty-seven 8-cycles occur.

Among elements of the base matrix, elements with the value of 1 are replaced with sub-matrices mapped to the code rate of ½ and elements with the value of 0 (not illustrated) are filled with a zero matrix that has the same size as the sub-matrix. In the code rate ½, 24×24 sub-matrix is two. Each of the IDCM integer sum is 24.

A parity check matrix H from the base matrix can be expressed as shown in Equation (2).
H=[H1H2]=[IDQCM[2,3,4,5,10]|R₁, . . . , R₅]|IDQCM[1,23|R₆,R₇]] (2)

For example, sub-matrices Rᵢ of the QC-LDPC code with the code rate of ½ in accordance with the present invention are predefined as shown in Equation (3).

$${R}_{1} = [ \begin{matrix}28 & 0 & 0 & 0 \\ 0 & 0 & 0 & 48 \\ 1 & 0 & 0 & 0 \\ 0 & 0 & 38 & 0\end{matrix} ] , {R}_{2} = [ \begin{matrix}0 & 0 & 0 & 9 \\ 39 & 0 & 0 & 0 \\ 0 & 0 & 15 & 0 \\ 0 & 2 & 0 & 0\end{matrix} ] , {R}_{3} = [ \begin{matrix}0 & 0 & 43 & 0 \\ 0 & 0 & 0 & 0 \\ 0 & 0 & 45 & 0 \\ 41 & 0 & 0 & 0\end{matrix} ] \\ {R}_{4} = [ \begin{matrix}46 & 0 & 0 & 0 \\ 0 & 0 & 51 & 0 \\ 0 & 0 & 0 & 7 \\ 0 & 25 & 0 & 0\end{matrix} ] , {R}_{5} = [ \begin{matrix}0 & 0 & 0 & 0 \\ 0 & 0 & 13 & 0 \\ 42 & 0 & 0 & 0 \\ 0 & 0 & 47 & 0\end{matrix} ] , {R}_{6} = [ \begin{matrix}0 & 33 & 0 & 0 \\ 0 & 0 & 8 & 0 \\ 4 & 0 & 0 & 0 \\ 0 & 0 & 0 & 18\end{matrix} ] , \\ {R}_{7} = [ \begin{matrix}0 & 0 & 0 & 44 \\ 37 & 0 & 0 & 0 \\ 0 & 12 & 0 & 0 \\ 0 & 0 & 49 & 0\end{matrix} ] \qquad ( 3 )$$

As described above, the sub-matrices Rᵢ are constructed with small-sized block matrices. For example, the block matrices include a zero matrix, a unit matrix and a quasi-cyclic matrix generated by shifting the unit matrix to the right by a predefined value. For example, the value of 28 or 48 shown in Equation (3) is a value by which the unit matrix is shifted to the right. In the sub-matrix R₁, the first column is constructed with a block matrix rather than two zero matrices and the second column is constructed with a zero matrix. Thus, elements with the value of 1 are irregularly distributed inside the sub-matrix R₁ constructed with the block matrixes. The parity check matrix are constructed with the sub-matrices. Ths sub-matrixes include irrgular disributed elements with the value of 1 even though a base matrix is regularly distributed. The finally generated parity check matrix is constructed such that the elements with the value of 1 are iregularly distributed.

On the other hand, to eliminate an inverse matrix operation in the coding process, a sub-matrix of the highest sub-matrix index of the last row is replaced with a predefined matrix R_{c} for eliminating the inverse matrix operation. The matrix for eliminating the inverse matrix operation can be computed by adding an identity matrix to the sub-matrix of the highest sub-matrix index as shown in Equation (4).
R_{c}=Rₘₐₓ+I (4)

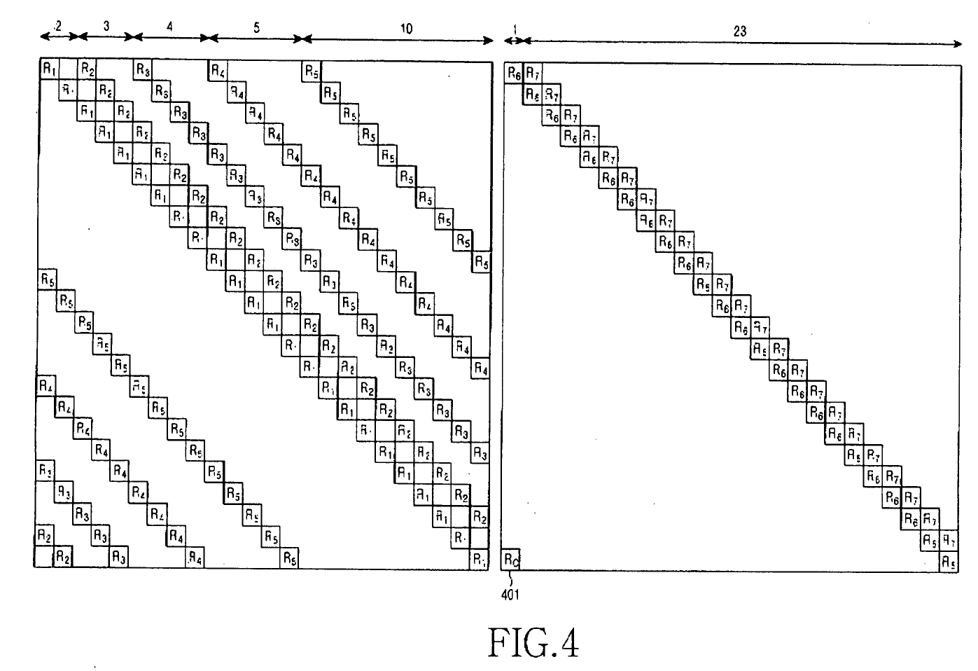

FIG. 4 illustrates an example of a parity check matrix generated by replacing IDCMs for constructing the base matrix of FIG. 3 with IDQCMs.

Among the sub-matrices for constructing IDQCM [1,23], the sub-matrix R₇ 401 of the highest sub-matrix index of the last row is replaced with the matrix R_{c} for eliminating the inverse matrix operation. That is, the sub-matrix R₇ of the last row in the parity check matrix H of Equation (2) is included in H2, and IDQCM [1,23|R₆,R₇] mapped to H2 is rewritten as shown in Equation (5).

$$H 2 = IDQCM [ 1 , 23 \vert {R}_{6} , {R}_{7} ] = [ \begin{matrix}⋰ & ⋰ & & & \\ & ⋰ & ⋰ & & \\ & & {R}_{6} & {R}_{7} & \\ & & & {R}_{6} & {R}_{7} \\ {R}_{C} & & & & {R}_{6}\end{matrix} ] \qquad ( 5 )$$

In the same manner as a parity check matrix process relative to the code rate of ½, a base matrix of a QC-LDPC code with a code rate of ⅔ is generated by combining IDCM [1,2,3,10], IDCM [4,5,7], and IDCM [1,15]. The base matrix B can be expressed as shown in Equation (6).
B=[IDCM[1,2,3,10]|IDCM[4,5,7]|IDCM[1,15]] (6)

A parity check matrix H from the base matrix of the Equation (6) can be expressed as shown in Equation (7). In the code rate ⅔, 16×16 sub-matrix is three. Each of the IDCM integer sum is 16.
H=[H1|H2|H3]=[IDQCM[1,2,3,10|R₁, . . . ,R₄]|IDQCM[4,5,7|R₅,R₆,R₇]|
IDQCM[1,15|R₈,R₉]] (7)

For example, sub-matrices Rᵢ of the QC-LDPC code with the code rate ⅔ in accordance with the present invention are predefined as shown in Equation (8).

$${R}_{1} = [ \begin{matrix}21 & 0 & 0 & 0 \\ 0 & 22 & 0 & 0 \\ 51 & 0 & 0 & 21 \\ 0 & 0 & 21 & 0\end{matrix} ] , {R}_{2} = [ \begin{matrix}0 & 38 & 0 & 15 \\ 40 & 0 & 0 & 0 \\ 0 & 0 & 37 & 0 \\ 23 & 25 & 0 & 0\end{matrix} ] , {R}_{3} = [ \begin{matrix}0 & 0 & 28 & 0 \\ 0 & 0 & 44 & 0 \\ 46 & 0 & 0 & 0 \\ 0 & 0 & 0 & 0\end{matrix} ] , \\ {R}_{4} = [ \begin{matrix}0 & 49 & 0 & 0 \\ 0 & 0 & 0 & 17 \\ 0 & 36 & 0 & 0 \\ 12 & 0 & 20 & 0\end{matrix} ] , {R}_{5} = [ \begin{matrix}0 & 49 & 0 & 17 \\ 24 & 0 & 0 & 0 \\ 36 & 0 & 0 & 0 \\ 0 & 0 & 12 & 0\end{matrix} ] , {R}_{6} = [ \begin{matrix}0 & 0 & 26 & 0 \\ 0 & 14 & 0 & 03 \\ 14 & 0 & 0 & 0 \\ 6 & 0 & 0 & 0\end{matrix} ] , \\ {R}_{7} = [ \begin{matrix}47 & 0 & 0 & 0 \\ 0 & 2 & 0 & 0 \\ 0 & 0 & 48 & 0 \\ 30 & 0 & 0 & 33\end{matrix} ] , {R}_{8} = [ \begin{matrix}0 & 5 & 0 & 0 \\ 0 & 0 & 41 & 0 \\ 39 & 0 & 0 & 0 \\ 0 & 0 & 0 & 42\end{matrix} ] , {R}_{9} = [ \begin{matrix}0 & 0 & 0 & 19 \\ 35 & 0 & 0 & 0 \\ 0 & 9 & 0 & 0 \\ 0 & 0 & 4 & 0\end{matrix} ] \qquad ( 8 )$$

As in the code rate of ½, the above-described sub-matirxes are constructed with small-sized block matrices.

Further, a sub-matrix of the highest sub-matrix index of the last row is replaced with a predefined matrix R_{c} for eliminating the inverse matrix operation in the coding process. Because the sub-matrix of the highest sub-matrix index is R₉ in the parity check matrix for the code rate of ⅔, the matrix for eliminating the inverse matrix operation R_{c}=R₉+I. That is, the sub-matrix R₉ of the last row in the parity check matrix H of Equation (7) is included in H3, and IDQCM [1,15|R₈,R₉] mapped to H3 is rewritten as shown in Equation (9).

$$H 3 = IDQCM [ 1 , 15 \vert {R}_{8} , {R}_{9} ] = [ \begin{matrix}⋰ & ⋰ & & & \\ & ⋰ & ⋰ & & \\ & & {R}_{8} & {R}_{9} & \\ & & & {R}_{8} & {R}_{9} \\ {R}_{C} & & & & {R}_{8}\end{matrix} ] \qquad ( 9 )$$

A base matrix of a QC-LDPC code with the code rate of ¾ is generated by combining IDCM [1,2,3,6], IDCM [1,4,7], IDCM [2,5,5], and IDCM [1,11]. The base matrix B can be expressed as shown in Equation (10).
B=[IDCM[1,2,3,6]|IDCM[1,4,7]|IDCM[2,5,5]IDCM[1,11]] (10)

A parity check matrix H from the base matrix of the Equation (10) can be expressed as shown in Equation (11). In the code rate ¾, 12×12 sub-matrix is four. Each of the IDCM integer sum is 12.
H=[H1|H2|H3|H4]=[IDQCM[1,2,3,6|R₁, . . . , R₄]|IDQCM[1,4,7|R₅,R₆,R₇]|
IDQCM[2,5,5|R₈,R₉,R₁₀]|IDQCM[1,11|R₁₁,R₁₂]] (11)

For example, sub-matrices Rᵢ of a QC-LDPC code with the code rate of ¾ in accordance with the present invention are predefined as shown in Equation (12).

$${R}_{1} = [ \begin{matrix}50 & 0 & 2 & 0 \\ 0 & 10 & 0 & 0 \\ 67 & 0 & 0 & 50 \\ 0 & 0 & 40 & 0\end{matrix} ] , {R}_{2} = [ \begin{matrix}0 & 18 & 0 & 58 \\ 56 & 0 & 0 & 0 \\ 0 & 0 & 48 & 0 \\ 8 & 60 & 0 & 0\end{matrix} ] , {R}_{3} = [ \begin{matrix}0 & 0 & 17 & 0 \\ 0 & 55 & 0 & 0 \\ 70 & 0 & 0 & 0 \\ 0 & 0 & 30 & 0\end{matrix} ] , \\ {R}_{4} = [ \begin{matrix}0 & 5 & 0 & 0 \\ 0 & 0 & 29 & 35 \\ 0 & 11 & 0 & 0 \\ 38 & 0 & 0 & 0\end{matrix} ] , {R}_{5} = [ \begin{matrix}0 & 0 & 0 & 46 \\ 0 & 27 & 0 & 0 \\ 0 & 0 & 22 & 0 \\ 23 & 0 & 0 & 0\end{matrix} ] , {R}_{6} = [ \begin{matrix}0 & 15 & 0 & 0 \\ 0 & 0 & 0 & 39 \\ 49 & 0 & 0 & 0 \\ 0 & 0 & 24 & 0\end{matrix} ] , \\ {R}_{7} = [ \begin{matrix}44 & 0 & 0 & 0 \\ 0 & 0 & 0 & 21 \\ 0 & 0 & 16 & 0 \\ 0 & 31 & 0 & 0\end{matrix} ] , {R}_{8} = [ \begin{matrix}0 & 0 & 0 & 41 \\ 0 & 47 & 0 & 0 \\ 0 & 0 & 52 & 0 \\ 63 & 0 & 0 & 0\end{matrix} ] , {R}_{9} = [ \begin{matrix}0 & 0 & 54 & 0 \\ 0 & 10 & 0 & 34 \\ 7 & 0 & 0 & 0 \\ 0 & 64 & 0 & 0\end{matrix} ] , \\ {R}_{10} = [ \begin{matrix}0 & 28 & 0 & 0 \\ 0 & 0 & 0 & 25 \\ 13 & 0 & 0 & 0 \\ 0 & 0 & 4 & 0\end{matrix} ] , {R}_{11} = [ \begin{matrix}0 & 36 & 0 & 0 \\ 0 & 0 & 43 & 0 \\ 42 & 0 & 0 & 0 \\ 0 & 0 & 0 & 71\end{matrix} ] , {R}_{12} = [ \begin{matrix}0 & 0 & 0 & 45 \\ 53 & 0 & 0 & 0 \\ 0 & 6 & 0 & 0 \\ 0 & 0 & 62 & 0\end{matrix} ] \qquad ( 12 )$$

Also in this case, the sub-matrices are constructed with small-sized block matrices.

Further, a sub-matrix of the highest sub-matrix index of the last row is replaced with a predefined matrix R_{c} for eliminating the inverse matrix operation in the coding process. A matrix ( R_{c}=R₁₂+I) for eliminating an inverse matrix operation is computed from the sub-matrix of the highest sub-matrix index in a parity check matrix for the code rate of ¾. The sub-matrix R₁₂ of the last row in the parity check matrix H of Equation (11) is included in H4, and IDQCM [1,11|R₁₁,R₁₂] mapped to H4 is rewritten as shown in Equation (13).

$$\begin{matrix}H 4 = IDQCM [ 1 , 11 \vert R 11 , R 12 ] \\ = [ \begin{matrix}R 11 & R 12 & & & \\ & ⋰ & ⋰ & & \\ & & R 11 & R 12 & \\ & & & R 11 & R 12 \\ {R}_{C} & & & & R 11\end{matrix} ]\end{matrix} \qquad ( 13 )$$

The parity check matrix can be generated by a parity check matrix generator (not illustrated) in a communication system. Next, a process for generating the parity check matrix will be briefly described.

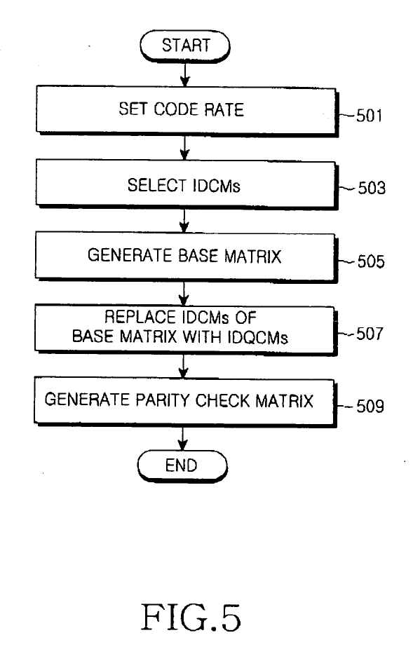

FIG. 5 is a flowchart illustrating the process for generating the parity check matrix in accordance with the present invention.

Referring to FIG. 5, the parity check matrix generator sets a code rate for generating the parity check matrix in step 501 and then proceeds to step 503.

The parity check matrix generator selects at least two IDCMs mapped to the set code rate in step 503 and then proceeds to step 505.

The parity check matrix generator generates a base matrix by combining the selected IDCMs in step 505 and then proceeds to step 507.

The parity check matrix generator replaces IDCMs forming the base matrix with IDQCMs mapped thereto in step 507 and then proceeds to step 509.

The IDQCMs are generated by replacing elements with the value of 1 constructing the IDCMs with at least one predefined sub-matrix, i.e., irregular sub-matrices. The sub-matrices are constructed with small-sized block matrices. The block matrices include at least one of a zero matrix, a unit matrix and a quasi-cyclic matrix generated by shifting the unit matrix to the right by a predefined value. In this case, the sub-matrices are irregular sub-matrices in which the block matrices are constructed irregularly.

Further, the parity check matrix generator replaces a sub-matrix of the highest sub-matrix index of the last row with a predefined matrix for eliminating the inverse matrix operation. The matrix for eliminating the inverse matrix operation can be generated by adding an identity matrix to the sub-matrix of the highest sub-matrix index of the last row among the sub-matrices. That is, the inverse matrix operation is eliminated using the matrix for eliminating the inverse matrix operation during the coding process.

In step 509, the parity check matrix generator generates a parity check matrix through the replacement such that a 4-cycle or 6-cylce does not occur.

As is apparent from the above description, an LDPC code construction method of the present invention can improve the decoding performance by implementing a parity check matrix from which 4-cycles or 6-cycles that adversely affect the LDPC code performance are completely eliminated.

Moreover, the LDPC code construction method of the present invention can minimize the coding complexity by eliminating an inverse matrix operation in a coding process.

Although the exemplary embodiments of the present invention have been disclosed for illustrative purposes, those skilled in the art will appreciate that various modifications, additions, and substitutions are possible, without departing from the scope of the present invention. Therefore, the present invention is not limited to the above-described embodiments, but is defined by the following claims, along with their full scope of equivalents.

What is claimed is:

1. A method for generating a parity check matrix of a Low Density Parity Check (LDPC) code, comprising the steps of:
generating a base matrix in which elements with a value of 1 are arranged at predefined distances; and
replacing the elements with the value of 1 in the base matrix with predefined sub-matrices and generating a parity check matrix.

2. The method of claim 1, wherein the step of generating the base matrix comprises the steps of:
setting a code rate of the LDPC code;
generating at least two Integer Distance Cyclic Matrices (IDCMs) mapped to the code rate; and
arranging the at least two IDCMs and generating the base matrix.

3. The method of claim 2, wherein the step of generating the parity check matrix comprises the steps of:
replacing the at least two IDCMs constructing the base matrix with Integer Distance Quasi-Cyclic Matrices (IDQCMs) constructed by-the predefined sub-matrices; and
replacing a sub-matrix of a highest sub-matrix index of a last row among the sub-matrices with a predefined matrix for eliminating an inverse matrix operation.

4. The method of claim 3, wherein the matrix for eliminating the inverse matrix operation is generated by adding an identity matrix to the sub-matrix of the highest sub-matrix index of the last row among the sub-matrices.

5. The method of claim 1, wherein the sub-matrices comprise at least one block matrix.

6. The method of claim 5, wherein the sub-matrices are irregular sub-matrices in which the at least one block matrix is constructed irregularly.

7. The method of claim 5, wherein the at least one block matrix comprises at least one of a zero matrix, a unit matrix and a quasi-cyclic matrix generated by shifting the unit matrix to the right by a predefined value.

8. The method of claim 2, wherein when the code rate is ½, the step of generating the base matrix comprises the steps of:
generating two 24×24 IDCMs mapped to the code rate of ½; and
arranging the two IDCMs and generating the base matrix.

9. The method of claim 8, wherein a first IDCM. of the two IDCMs is generated by shifting a row, in which distances between the elements with the value of 1 are 2, 3, 4, 5, and 10, to the right by 1, and a second IDCM of the two IDCMs is generated by shifting a row, in which distances between the elements with the value of 1 are 1 and 23, to the right by 1.

10. The method of claim 9, wherein the step of generating the parity check matrix comprises the step of:
replacing the first and second IDCMs constructing the base matrix with first and second IDQCMs.

11. The method of claim 10, wherein the first and second IDQCMs are constructed by at least one predefined sub-matrix mapped to elements with the value of 1 of the first and second IDCMs, respectively, the at least one predefined sub-matrix being defined by:
$${R}_{1} = [ \begin{matrix}28 & 0 & 0 & 0 \\ 0 & 0 & 0 & 48 \\ 1 & 0 & 0 & 0 \\ 0 & 0 & 38 & 0\end{matrix} ] , {R}_{2} = [ \begin{matrix}0 & 0 & 0 & 9 \\ 39 & 0 & 0 & 0 \\ 0 & 0 & 15 & 0 \\ 0 & 2 & 0 & 0\end{matrix} ] , {R}_{3} = [ \begin{matrix}0 & 0 & 43 & 0 \\ 0 & 0 & 0 & 0 \\ 0 & 0 & 45 & 0 \\ 41 & 0 & 0 & 0\end{matrix} ]$$
$${R}_{4} = [ \begin{matrix}46 & 0 & 0 & 0 \\ 0 & 0 & 51 & 0 \\ 0 & 0 & 0 & 7 \\ 0 & 25 & 0 & 0\end{matrix} ] , {R}_{5} = [ \begin{matrix}0 & 0 & 0 & 0 \\ 0 & 0 & 13 & 0 \\ 42 & 0 & 0 & 0 \\ 0 & 0 & 47 & 0\end{matrix} ] , {R}_{6} = [ \begin{matrix}0 & 33 & 0 & 0 \\ 0 & 0 & 8 & 0 \\ 4 & 0 & 0 & 0 \\ 0 & 0 & 0 & 18\end{matrix} ] , \\ and$$
$${R}_{7} = [ \begin{matrix}0 & 0 & 0 & 44 \\ 37 & 0 & 0 & 0 \\ 0 & 12 & 0 & 0 \\ 0 & 0 & 49 & 0\end{matrix} ] .$$

12. The method of claim 11, wherein a sub-matrix of a highest sub-matrix index of a last row among the sub-matrices is replaced with a matrix for eliminating an inverse matrix operation generated by adding an identity matrix to the sub-matrix.

13. The method of claim 2, wherein when the code rate is ⅔, the step of generating the base matrix comprises the steps of:
generating three 16×16 IDCMs mapped to the code rate of ⅔; and
arranging the three IDCMs and generating the base matrix.

14. The method of claim 13, wherein a first IDCM of the three IDCMs is generated by shifting a row, in which distances between the elements with the value of 1 are 1, 2, 3, and 10, to the right by 1, a second IDCM of the three IDCMs is generated by shifting a row, in which distances between the elements with the value of 1 are 4, 5 and 7, to the right by 1, and a third IDCM of the three IDCMs is generated by shifting a row, in which distances between the elements with the value of 1 are 1 and 15, to the right by 1.

15. The method of claim 14, wherein the step of generating the parity check matrix comprises the step of:
replacing the first, second, and third IDCMs constructing the base matrix with first, second, and third IDQCMs.

16. The method of claim 15, wherein the first, second, and third IDQCMs are constructed by at least one predefined sub-matrix mapped to elements with the value of 1 of the first, second, and third IDCMs, respectively, the at least one predefined sub-matrix being defined by:
$${R}_{1} = [ \begin{matrix}21 & 0 & 0 & 0 \\ 0 & 22 & 0 & 0 \\ 51 & 0 & 0 & 21 \\ 0 & 0 & 20 & 0\end{matrix} ] , {R}_{2} = [ \begin{matrix}0 & 38 & 0 & 15 \\ 40 & 0 & 0 & 0 \\ 0 & 0 & 37 & 0 \\ 23 & 25 & 0 & 0\end{matrix} ] , {R}_{3} = [ \begin{matrix}0 & 0 & 28 & 0 \\ 0 & 0 & 44 & 0 \\ 46 & 0 & 0 & 0 \\ 0 & 0 & 0 & 0\end{matrix} ] , \\ {R}_{4} = [ \begin{matrix}0 & 49 & 0 & 0 \\ 0 & 0 & 0 & 17 \\ 0 & 36 & 0 & 0 \\ 12 & 0 & 20 & 0\end{matrix} ] , {R}_{5} = [ \begin{matrix}0 & 49 & 0 & 17 \\ 24 & 0 & 0 & 0 \\ 36 & 0 & 0 & 0 \\ 0 & 0 & 12 & 0\end{matrix} ] , {R}_{6} = [ \begin{matrix}0 & 0 & 26 & 0 \\ 0 & 14 & 0 & 03 \\ 14 & 0 & 0 & 0 \\ 6 & 0 & 0 & 0\end{matrix} ] , \\ {R}_{7} = [ \begin{matrix}47 & 0 & 0 & 0 \\ 0 & 2 & 0 & 0 \\ 0 & 0 & 48 & 0 \\ 30 & 0 & 0 & 33\end{matrix} ] , {R}_{8} = [ \begin{matrix}0 & 5 & 0 & 0 \\ 0 & 0 & 41 & 0 \\ 39 & 0 & 0 & 0 \\ 0 & 0 & 0 & 42\end{matrix} ] , and {R}_{9} = [ \begin{matrix}0 & 0 & 0 & 19 \\ 35 & 0 & 0 & 0 \\ 0 & 9 & 0 & 0 \\ 0 & 0 & 4 & 0\end{matrix} ] .$$

17. The method of claim 16, wherein a sub-matrix of a highest sub-matrix index of a last row among the sub-matrices is replaced with a matrix for eliminating an inverse matrix operation generated by adding an identity matrix to the sub-matrix.

18. The method of claim 2, wherein when the code rate is ¾, the step of generating the base matrix comprises the steps of:
generating four 12×12 IDCMs mapped to the code rate of ¾; and
arranging the four IDCMs and generating the base matrix.

19. The method of claim 18, wherein a first IDCM of the four IDCMs is generated by shifting a row, in which distances between the elements with the value of 1 are 1, 2, 3, and 6, to the right by 1, a second IDCM of the four IDCMs is generated by shifting a row, in which distances between the elements with the value of 1 are 1, 4, and 7, to the right by 1, a third IDCM of the four IDCMs is generated by shifting a row, in which distances between the elements with the value of 1 are 2, 5, and 5, to the right by 1, and a fourth IDCM of the four IDCMs is generated by shifting a row, in which distances between the elements with the value of 1 are 1 and 11, to the right by 1.

20. The method of claim 19, wherein the step of generating the parity check matrix comprises the step of:
replacing the first, second, third, and fourth IDCMs constructing the base matrix with first, second, third, and fourth IDQCMs.

21. The method of claim 20, wherein the first, second, third, and fourth IDQCMs are constructed by at least one predefined sub-matrix mapped to elements with the value of 1 of the first, second, third, and fourth IDCMs, respectively, the at least one predefined sub-matrix being defined by:
$${R}_{1} = [ \begin{matrix}50 & 0 & 2 & 0 \\ 0 & 10 & 0 & 0 \\ 67 & 0 & 0 & 50 \\ 0 & 0 & 40 & 0\end{matrix} ] , {R}_{2} = [ \begin{matrix}0 & 18 & 0 & 58 \\ 56 & 0 & 0 & 0 \\ 0 & 0 & 48 & 0 \\ 8 & 60 & 0 & 0\end{matrix} ] , {R}_{3} = [ \begin{matrix}0 & 0 & 17 & 0 \\ 0 & 55 & 0 & 0 \\ 70 & 0 & 0 & 0 \\ 0 & 0 & 30 & 0\end{matrix} ] , \\ {R}_{4} = [ \begin{matrix}0 & 5 & 0 & 0 \\ 0 & 0 & 29 & 35 \\ 0 & 11 & 0 & 0 \\ 38 & 0 & 0 & 0\end{matrix} ] , {R}_{5} = [ \begin{matrix}0 & 0 & 0 & 46 \\ 0 & 27 & 0 & 0 \\ 0 & 0 & 22 & 0 \\ 23 & 0 & 0 & 0\end{matrix} ] , {R}_{6} = [ \begin{matrix}0 & 15 & 0 & 0 \\ 0 & 0 & 0 & 39 \\ 49 & 0 & 0 & 0 \\ 0 & 0 & 24 & 0\end{matrix} ] , \\ {R}_{7} = [ \begin{matrix}44 & 0 & 0 & 0 \\ 0 & 0 & 0 & 21 \\ 0 & 0 & 16 & 0 \\ 0 & 31 & 0 & 0\end{matrix} ] , {R}_{8} = [ \begin{matrix}0 & 0 & 0 & 41 \\ 0 & 47 & 0 & 0 \\ 0 & 0 & 52 & 0 \\ 63 & 0 & 0 & 0\end{matrix} ] , {R}_{9} = [ \begin{matrix}0 & 0 & 54 & 0 \\ 0 & 10 & 0 & 34 \\ 7 & 0 & 0 & 0 \\ 0 & 64 & 0 & 0\end{matrix} ] , \\ {R}_{10} = [ \begin{matrix}0 & 28 & 0 & 0 \\ 0 & 0 & 0 & 25 \\ 13 & 0 & 0 & 0 \\ 0 & 0 & 4 & 0\end{matrix} ] , {R}_{11} = [ \begin{matrix}0 & 36 & 0 & 0 \\ 0 & 0 & 43 & 0 \\ 42 & 0 & 0 & 0 \\ 0 & 0 & 0 & 71\end{matrix} ] , and {R}_{12} = [ \begin{matrix}0 & 0 & 0 & 45 \\ 53 & 0 & 0 & 0 \\ 0 & 6 & 0 & 0 \\ 0 & 0 & 62 & 0\end{matrix} ] .$$

22. The method of claim 21, wherein a sub-matrix of a highest sub-matrix index of a last row among the sub-matrices is replaced with a matrix for eliminating an inverse matrix operation generated by adding an identity matrix to the sub-matrix.
